(19) United States
(12) Patent Application Publication
(10) Pub. No.: US 2023/0417807 A1
(43) Pub. Date: Dec. 28, 2023

(54) Detecting a Faulty Voltage Sensor of a Controller in an Onboard Electrical System of a Vehicle

(71) Applicant: Bayerische Motoren Werke Aktiengesellschaft, Muenchen (DE)

(72) Inventor: David MAIER, Muenchen (DE)

(21) Appl. No.: 18/039,351

(22) PCT Filed: Nov. 5, 2021
(86) PCT No.: PCT/EP2021/080772

§ 371 Date: May 30, 2023

(30) Foreign Application Priority Data
Dec. 17, 2020 (DE) 10 2020 134 072.9

(51) Int. Cl. G01R 19/10; G01R 35/00

(52) U.S. Cl. CPC G01R 19/10; G01R 35/00

(57) ABSTRACT

A method for detecting a faulty voltage sensor of a group of n≥3 voltage sensors of controllers in an onboard electrical system of a vehicle, wherein (a) voltage measurement values from n−1 voltage sensors are averaged, (b) the deviation of a voltage measurement value of the remaining voltage sensor from the averaged voltage measurement value is determined, and (c) if the deviation satisfies a specified criterion, an error message relating to a fault of the remaining voltage sensor is output and at least steps (a) to (b) are carried out for the voltage sensors in a commutated manner.

### BACKGROUND AND SUMMARY OF THE INVENTION

The invention relates to a method for detecting a defective voltage sensor of a controller in an onboard electrical system of a vehicle. The invention further relates to a vehicle having an onboard electrical system which is operated at an equal rated voltage, comprising a plurality of controllers, each having at least one voltage sensor. The invention can be applied in a particularly advantageous manner to hybrid vehicles and fully electric vehicles.

The detection of defective voltage sensors of controllers which are located within an onboard (sub-) system operating at an equal rated voltage is known, wherein voltage measurement values thereof are compared with voltage measurement values of at least one reference voltage sensor. The at least one reference voltage sensor is typically arranged in a separate reference module. This is disadvantageous, in that the reference module generates higher costs.

The object of to the present invention is to at least partially eliminate the disadvantages of the prior art and, in particular, to provide a cost-effective option for the identification of defective voltage sensors of controllers.

This object is fulfilled by the features of the independent claims. Preferred embodiments can particularly be identified from the dependent claims.

This object is fulfilled by a method for detecting a defective voltage sensor from a group of n (where n is a whole number)≥3 voltage sensors of controllers in an onboard electrical system of a vehicle, wherein:
(a) voltage measurement values from n−1 voltage sensors are averaged,
(b) the deviation of a voltage measurement value of the remaining voltage sensor from the averaged voltage measurement value is determined, and
(c) if the deviation satisfies a specified criterion, an output of an error message relating to a fault state of the remaining voltage sensor is generated.

By this mutual comparison of voltage measurement values from the voltage sensors of controllers only, reference voltage sensors can be omitted, thereby eliminating costs for the procurement of reference voltage sensors, and for the installation thereof.

This method can be executed for a minimum of three voltage sensors. It is particularly appropriate for a circumstance in which one of the voltage sensors is defective.

In particular, an onboard system voltage is measured by means of the voltage sensors. A defective voltage sensor can be understood as a failed voltage sensor, or as a voltage sensor which measures the onboard system voltage incorrectly, e.g., which outputs significantly excessively high or excessively low voltage measurement values.

A controller can comprise one or more voltage sensors.

Averaging can be, e.g., arithmetic averaging.

The deviation can be a difference, for example a signed difference or an absolute difference.

The criterion can comprise a single criterion, or can comprise a plurality of criteria, which must be fulfilled in combination for the generation of an error message.

By the execution of at least steps (a) to (b) for the voltage sensors in a commutated manner, it is understood that either steps (a) and (b) are executed in a commutated manner, and thereafter step (c), or that steps (a) to (c) are executed in a commutated manner.

By the execution of steps (a) to (b) in a commutated manner, it is understood that, from the group of voltage sensors S₁, . . . , Sₙ involved in the method, a specific voltage sensor Sᵢ from this group is determined, the measured voltage measurement value of which is compared with an averaged voltage measurement value U of the remaining voltage sensors in this group. In other words, the deviation of a voltage measurement value of this voltage sensor Sᵢ from the averaged voltage measurement value U of voltage measurement values from the remaining voltage sensors is determined. The deviation is then determined for another voltage sensor Sⱼ from this group, etc. This process can be executed until the deviation for all the voltage sensors S₁, . . . , Sₙ involved in the method has been determined. Commutation can also be described as cyclical permutation.

For example, the method can be executed for a total of n voltage sensors S₁, S₂, . . . , Sₙ, such that the voltage measurement values U₁, . . . , Uᵢ₋₁, Uᵢ₊₁, . . . , Uₙ of the voltage sensors S₁, Sᵢ₋₁, Sᵢ₊₁, . . . , Sₙ are measured and averaged, thereby generating an averaged voltage measurement value U [U₁, . . . , Uᵢ₋₁, Uᵢ₊₁, . . . , Uₙ]. This averaged voltage measurement value U is compared by taking the difference with the voltage measurement value Uᵢ of the voltage sensor Sᵢ which is not included in averaging, such that e.g. ΔUᵢ=|U−Uᵢ| is calculated. This determination of the deviation is then executed e.g. for the voltage sensor Sᵢ₊₁, and thereafter particularly until such time as the determination of the deviation has been executed for all the voltage sensors Sᵢ, where i=[1, . . . , n]. This can also be expressed such that at least the steps (a) and (b) are executed for i=[1, . . . , n] in a permutated manner.

According to one configuration, steps (a) and (b) are executed for the voltage sensors in a commutated manner, and step (c) is executed further to the execution of a commutation cycle (i.e. further to the commutation or permutation of all the voltage sensors), wherein the criterion comprises the presence of a maximum deviation in the group of deviations which have been determined during the commutation cycle and, additionally, the achievement or overshoot of the maximum deviation from the averaged voltage measurement value by a stipulated tolerance or tolerance margin. This provides an advantage, in that a defective voltage sensor can be detected, even in the event of the involvement of a low number n of sensors in the method.

By the execution of only steps (a) and (b) in a commutated manner, n deviations or deviation values will have been determined or will be available in advance of step (c).

According to the criterion for the presence of the maximum deviation in the group of deviations which have been determined during the commutation cycle, it is determined which of the n deviations is the largest, particularly quantitatively. This can be implemented such that the deviation is an absolute or quantitative deviation. A check is then executed as to whether this maximum value ΔU_{i_max}=max {ΔU₁, . . . , ΔUₙ} achieves or overshoots a stipulated tolerance deviation ΔUₜₒₗ, e.g. whether |ΔU_{i_max}|≥ΔUₜₒₗ. The tolerance deviation can assume an arbitrary threshold value, but can assume a preferred threshold value which is stipulated e.g. by a manufacturer or designer of the onboard system. Consideration of the tolerance deviation prevents any output of an error message for voltage sensors Sᵢ, the voltage deviations ΔUᵢ of which lie within acceptable values, e.g. within customary component tolerances.

According to one configuration, steps (a) to (c) are executed for the voltage sensors in a commutated manner, and the criterion provided is that the deviation ΔUᵢ determined in step (b) achieves or exceeds a stipulated threshold value (“fault threshold value”) Uₜₕᵣ. Advantageously, this can be determined by computing technology in a particularly simple and uncomplex manner. In this configuration, steps (a) to (c) are executed for a specific voltage sensor Sᵢ which is not included in the calculation of the averaged voltage value U and, in step (c), a simple check is executed as to whether the associated voltage deviation ΔUᵢ (particularly the absolute voltage deviation |ΔUᵢ|) quantitatively exceeds the fault threshold value Uₜₕᵣ or otherwise. If this is the case, an error message output is generated, or otherwise not. The fault threshold value Uₜₕᵣ can assume an arbitrary threshold value, but can assume a preferred threshold value which is stipulated e.g. by a manufacturer or designer of the onboard system.

This configuration can be executed in a particularly advantageous manner, if the number n of voltage sensors involved in the method is at least five. In this case, the method, on the grounds of the sufficiently high number of voltage sensors involved in the calculation of the average value U, is such that the deviation in step (b) itself is determined with sufficient reliability, in the event that the defective voltage sensor is included therein. However, this minimum value nₘᵢₙ can also be stipulated as a value higher than five, e.g. by a manufacturer or designer of the onboard network. The higher the number n of sensors involved in the method, the more reliable this configuration will be.

According to one configuration, voltage measurement values are respectively measured at regular intervals and adjusted to a common sampling rate (resampling). This facilitates a comparison of voltage measurement values for a given time point, in the event that the voltage sensors assume different sampling rates.

According to one configuration, error messages are saved in an error memory for a stipulated time interval, and a voltage sensor is then classified as defective, in the event that a number of error messages saved for this voltage sensor in the error memory achieves or exceeds a stipulated number. This can also be described as “debouncing”. As a result, advantageously, a case can be prevented in which a functional, error-free voltage sensor is classified as defective on the grounds of short-term local effects, such as impedance fluctuations in the controller. As a result of debouncing, an error message is not generated until the voltage measurement value measured by a voltage sensor deviates from the voltage measurement values of the other voltage sensors more frequently, and over a longer term.

According to one configuration, the method, further to the classification of a voltage sensor as defective, is repeated for the remaining voltage sensors, provided that the number of remaining voltage sensors is at least three. The voltage sensor identified as defective is thus remove from the group of voltage sensors involved in the method, such that the method is only executed thereafter for the remaining voltage sensors. As a result, defective voltage sensors can continue to be identified, even if a defective voltage sensor has already been removed from the group of voltage sensors involved in the method. In particular, two or more defective voltage sensors can thus be identified in sequence.

According to one configuration, the method, prior to the detection of a defective voltage sensor, is executed for a number n of voltage sensors, wherein n=nₘᵢₙ, by means of a simple threshold value comparison and, further to the detection of the defective voltage sensor, is executed for 3≤n<nₘᵢₙ sensors, by means of a maximum value comparison. An advantage is thus achieved in that, if a sufficiently high number of voltage sensors are present, fault detection can be executed by means of a simple threshold value query whereas, if the number n is reduced below the minimum number nₘᵢₙ which is considered as meaningful by the exclusion of a defective voltage sensor, an automatic switchover to the maximum deviation determination method is executed, which is more reliable for small numbers of n<nₘᵢₙ.

According to one configuration, in the event that, further to the classification of a voltage sensor as defective, the method is repeated for the remaining voltage sensors and, additionally, a check is executed as to whether the voltage sensor which has been classified as defective continues to fulfil the deviation in the stipulated criterion at least once during a stipulated number of executions of the method and, if not, this voltage sensor is no longer classified as defective and, thereafter, the method is executed with the re-inclusion of this voltage sensor. In other words, a voltage sensor which is classified as defective can be reclassified as not defective or fault-free, and then reincluded in the method, in the event that, after a certain time period, this voltage sensor shows a deviation from the calculated averaged voltage measurement value U (which has been calculated without the inclusion thereof) which does not trigger the (fault) criterion. In a further development, this can be implemented such that the voltage sensor which has previously been classified as defective is reclassified as fault-free, and is reincluded in the method, provided that, for a stipulated number m of steps (a) to (c), it has been established that the deviation ΔU thereof lies within the maximum permissible deviation ΔU_{i_max} from the averaged voltage measurement value U determined by the other voltage sensors. This configuration is particularly advantageous in the event that a specific voltage sensor only fulfils the fault criterion on a temporary basis, particularly on the grounds of short-term external influences. A potential example comprises a measurement or control apparatus which does not monitor its own supply voltage, but monitors e.g. the voltage of a plurality of onboard (sub-) systems. In this case, if a cable connection, for servicing purposes, is interrupted temporarily, but nevertheless for a duration which exceeds the minimum time interval for fault detection, only a temporary, rather than a permanent fault is present in the system. This configuration is also particularly advantageous, if the initial number n of voltage sensors involved in the method is small, as the re-inclusion of the voltage sensor which is only temporarily classified as defective significantly increases the parent population of voltage sensors and thus, in turn, substantially enhances the reliability of the method.

The above-mentioned method is advantageously executed with an evaluation frequency of voltage measurement values which are measured or resampled by the voltage sensors of at least 2 Hz.

The object is also fulfilled by a vehicle having an onboard electrical system which is operated at an equal rated voltage, comprising a plurality of controllers, each having at least one voltage sensor, and comprising an evaluation device which is connected to the voltage sensors, and which is designed to receive voltage measurement values measured by the total of n≥3 voltage sensors, wherein the evaluation device is designed to execute the method according to one of the preceding claims. The vehicle can be configured in an analogous manner to the method, and comprises the same advantages.

The vehicle can be a terrestrial vehicle, such as a passenger car, a heavy goods vehicle, a motorcycle, a bus, etc. However, the vehicle can also be a watercraft, such as a ship, and/or an airborne vehicle such as an aircraft of a helicopter. The vehicle can be at least partially electrically powered, e.g. a hybrid vehicle, or can be a fully electrically powered vehicle.

The vehicle can be a vehicle which assumes the equal rated onboard electrical system voltage. However, the vehicle can also comprise a plurality of onboard sub-systems having different onboard sub-system voltages, wherein the method is then respectively applicable to the onboard sub-systems.

The above-mentioned properties, features and advantages of the present invention, and the manner whereby these are achieved, will be elucidated and clarified by reference to the following schematic description of an exemplary embodiment, which is described in greater detail with reference to the drawings.

### BRIEF DESCRIPTION OF THE DRAWINGS

FIG. 1 shows a flow diagram of the method according to a first exemplary embodiment;

FIG. 2 shows a flow diagram of the method according to a second exemplary embodiment; and

FIG. 3 shows a sketch of a potential diagnostic layout for the execution of the method according to the exemplary embodiments.

### DETAILED DESCRIPTION OF THE DRAWINGS

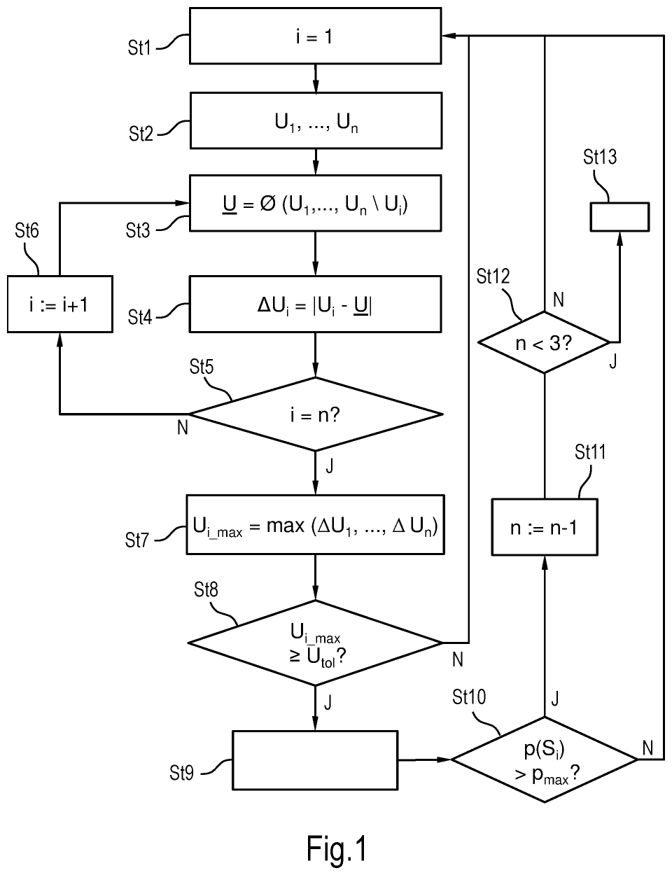

FIG. 1 shows a flow diagram of a method according to a first exemplary embodiment for i=1, . . . , n≥3 voltage sensors Sᵢ of controllers, wherein the voltage sensors Sᵢ detect an equal onboard system voltage of an onboard electrical system of a vehicle, e.g., a hybrid vehicle or a fully electrically powered vehicle.

In a first step St1, for exemplary purposes only, the index i is set at i=1.

In a second step St2, voltage measurement values U₁, . . . , Uₙ measured by all the voltage sensors S₁, . . . , Sₙ at the same time point are determined, optionally with the support of resampling.

In a third step St3, voltage measurement values {U₁, . . . , Uₙ\U₁}={U₂, . . . , Uₙ], e.g., are arithmetically averaged, as a result of which an average value U=Ø(U₂, . . . , Uₙ) is obtained.

In a fourth step St4, a deviation ΔU₁ of the voltage measurement value U₁ from the averaged voltage measurement value U is then determined and saved, and is expressed here, for exemplary purposes only, as an absolute value of the difference.

In a fifth step St5, a check is executed as to whether the index i has achieved the value n. If this is not the case (“N”), in step St6, the index is incrementally raised by one, and the process branches back to step St3. By means of this commutating loop, the deviation ΔU₁ is determined for all voltage measurement values Uᵢ and saved.

Conversely, if the index i has achieved the value n in the fifth step St5 (“J”), in a seventh step St7, the maximum ΔU_{i_max}=max(ΔU₁, . . . , ΔUₙ) is determined for all the previously calculated n deviations ΔU₁, . . . ΔUₙ.

In a subsequent eighth step St8, a check is executed as to whether the maximum ΔU_{i_max} has achieved or exceeded a tolerance deviation Uₜₒₗ, e.g., of 1 V. The tolerance deviation Uₜₒₗ corresponds to a threshold value which, in principle, is arbitrary, but is then subject to specific definition.

If this is not the case (“N”), the process branches back to step St1. Conversely, if this is the case (“J”) in a ninth step St9, an error message output with respect to a fault state of the remaining voltage sensor is delivered to an error memory, in which the error message is saved for a stipulated and time-limited duration.

Further to step St9, in a tenth step St10, a check is executed as to whether the number p(Sᵢ) of error messages saved in the error memory for the respective voltage sensors S₁, . . . , Sₙ exceeds a stipulated maximum value pₘₐₓ. If this is not the case (“N”), the process branches back to step St1. Conversely, if this is the case for a specific voltage sensor Sᵢ (“J”), an indication of the fault susceptibility of this particular voltage sensor Sᵢ is generated.

In a positive case (“J”), step St10 can also be followed by an eleventh step St11, wherein the voltage sensor Sᵢ which has been identified as defective is removed from the group of voltage sensors which are involved in the method such that, thereafter, the method is executed for only n=n−1 voltage sensors {S₁, . . . , Sₙ\Sᵢ}.

Subsequently to step St11, in a twelfth step St12, a check is executed as to whether the number of voltage sensors S₁, . . . , Sₙ still involved in the method undershoots the value of three. If this is not the case (“N”), a transition to step St1 is executed, or otherwise (“J”) the method is interrupted in step S13, optionally with the generation of a corresponding indication to this effect.

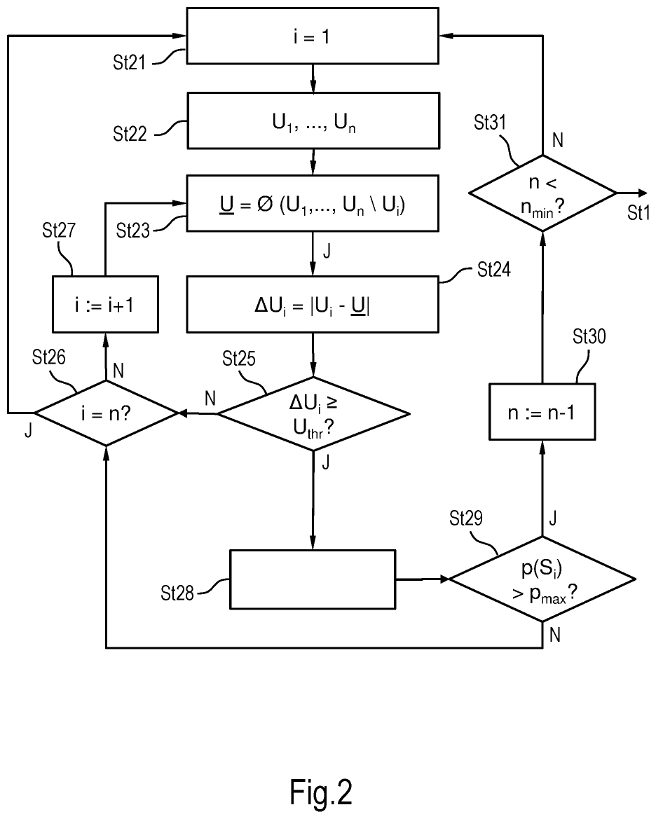

FIG. 2 shows an alternative flow diagram of a method according to a second exemplary embodiment for i=1, . . . , n=nₘᵢₙ≥5 voltage sensors Sᵢ of controllers, wherein the voltage sensors Sᵢ detect an equal onboard system voltage of an onboard electrical system of a vehicle, e.g. a hybrid vehicle or a fully electrically powered vehicle.

This method comprises a first four steps St21 to St24, which correspond to steps St1 to St4 according to FIG. 1. Step St24 is followed by a step St25, in which a check is executed as to whether the deviation ΔUᵢ has achieved or exceeded a stipulated fault threshold value Uₜₕᵣ. If this is not the case (“N”), the process branches off to a step St26, which is analogous to step St25 according to FIG. 1, in which a check is executed as to whether the index i has achieved the number n of voltage sensors S₁, . . . , Sₙ involved in the method. If this is the case (“J”), the process branches off to step St21, or otherwise (“N”) to step St27, which is analogous to step St6 according to FIG. 1, wherein i, for example, is incrementally raised by one, whereafter the method proceeds back to step St23.

If, however, it is detected in step St25 that the deviation ΔUᵢ has achieved or exceeded a stipulated fault threshold value Uₜₕᵣ (“J”), the process branches off to step St28, which is analogous to step St9 according to FIG. 1, which then proceeds to step St29, which corresponds to step St10 from FIG. 1. If the number p(Sᵢ) of error messages saved in the error memory for the respective voltage sensors S₁, . . . , Sₙ does not exceed a stipulated maximum value pₘₐₓ (“N”), the process branches off to step St26. If, conversely, it is detected in step St29 that the number p(Sᵢ) of error messages saved in the error memory for the respective voltage sensors S₁, . . . , Sₙ exceeds a stipulated maximum value pₘₐₓ (“J”), the process branches off to step St30, which is analogous to St11 according to FIG. 1.

Step St30 can be followed by a step St31, in which a check is executed as to whether, following the removal of a voltage sensor which has been classified as defective from the group of voltage sensors involved in the method, the number n of remaining voltage sensors involved in the method undershoots the minimum number nₘᵢₙ stipulated for the present exemplary embodiment or otherwise. If this is not the case (“N”), the process branches to step St21, or otherwise (“J”) the method executes a switchover to the exemplary embodiment represented in FIG. 1. The process thus branches off, e.g. to step St1 according to FIG. 1.

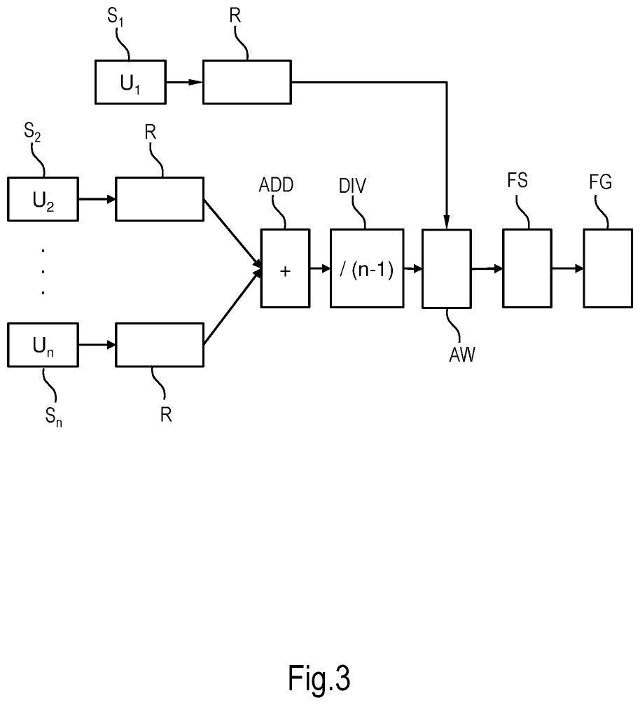

FIG. 3 shows a sketch of a potential diagnostic layout for the execution of steps St1 to St13 or St21 to St31 of the method according to the exemplary embodiments for n≥3 voltage sensors S₁, . . . , Sₙ wherein, in this case, for exemplary purposes, a check is executed on voltage sensor S₁, which is consequently not included in the generation of the average value.

Voltage measurement values Uₙ, . . . , Uₙ measured by the voltage sensors S₁, . . . , Sₙ are adjusted to a common sampling rate by means of respective resampling logics R. The (resampled) voltage measurement values U₂, . . . , Uₙ are then added together in a summing logic ADD and, in a division logic DIV, are divided by the number thereof (n−1). The resulting averaged value Ū, in an evaluation logic AW is then compared with the voltage measurement value U₁ according to the above-mentioned method(s), in order to determine whether an error message output is to be delivered to an error memory FS. If the number of error messages saved in the error memory FS for the voltage sensor S₁ exceeds a maximum permissible number pₘₐₓ, an error flag is posted on the error message memory FG, to which a response can be executed.

The above-mentioned logics and memories R, ADD, DIV, AW, FS, FG can be arbitrarily distributed over one or more electronic units. The error memory FS and the error message memory FG can thus constitute different data regions of a common memory or memory module. Likewise, the summing logic ADD, the division logic DIV and the evaluation logic AW can be integrated in a common logic module, such as a microcontroller, ASIC, FPGA, etc.

Although not represented in the exemplary embodiments, but available as an option, it can be provided that, further to the classification of a voltage sensor as defective, the method is repeated for the remaining voltage sensors and, additionally, a check is executed as to whether the voltage sensor which has been classified as defective continues to fulfil the stipulated criterion at least once during a given number of executions of the method and, if this is not the case, the voltage sensor concerned is no longer classified as defective, such that the method is executed thereafter with the re-inclusion of this voltage sensor.

Naturally, the present invention is not limited to the exemplary embodiments illustrated.

In general, by an indefinite article “a”, “an”, etc., a singular or a plural can be understood, particularly in the sense of “at least one” or “one or more”, etc., provided that this is not explicitly excluded, e.g. by the expression “exactly one”, etc.

A numerical indication can also comprise exactly the number indicated, or can incorporate a customary tolerance range, provided that this is not explicitly excluded.

### LIST OF REFERENCE SYMBOLS

ADD Summing logic
AW Evaluation logic
DIV Division logic
FS Error memory
FG Error message memory
i Index
n Number of voltage sensors
nₘᵢₙ Minimum number of voltage sensors
p(Uᵢ) Number of error messages saved in an error memory for a voltage sensor Sᵢ
pₘₐₓ Permissible maximum value of error messages saved in an error memory
R Resampling logic
Sᵢ i^{th} voltage sensor
St Process step
Uᵢ Voltage measured by the i^{th} voltage sensor
ΔU_{i_max} Maximum deviation ΔUᵢ
Uₜₕᵣ Error threshold value
Uₜₒₗ Tolerance deviation
U Averaged voltage
ΔUᵢ Deviation between Uᵢ and U

1.-10. (canceled)

11. A method for detecting a defective voltage sensor from a group of n≥3 voltage sensors of controllers in an onboard electrical system of a vehicle, the method comprising:
(a) averaging voltage measurement values from n−1 voltage sensors;
(b) determining a deviation of a voltage measurement value of a remaining voltage sensor from an averaged voltage measurement value; and
(c) outputting an error message relating to a fault state of the remaining voltage sensor when the deviation satisfies a specified criterion;
wherein at least steps (a) and (b) are executed for the voltage sensors in a commutated manner.

12. The method according to claim 11, wherein:
step (c) is executed further to execution of a commutation cycle,
wherein the criterion comprises a presence of a maximum deviation in a group of deviations which have been determined during the commutation cycle and, additionally, an achievement or overshoot of the maximum deviation from the averaged voltage measurement value by a stipulated tolerance deviation.

13. The method according to claim 11, wherein steps (a) to (c) are executed for the voltage sensors in a commutated manner, and the criterion comprises an achievement or overshoot of a stipulated threshold value by the deviation determined in step (b).

14. The method according to claim 13, wherein n is equal to or greater than a minimum number nₘᵢₙ of voltage sensors, wherein nₘᵢₙ≥5.

15. The method according to claim 11, wherein the voltage measurement values are respectively measured at regular intervals and adjusted to a common sampling rate.

16. The method according to claim 11, wherein error messages are saved in an error memory for a stipulated time interval, and a first voltage sensor is then classified as defective, in an event that a number of error messages saved for the first voltage sensor in the error memory achieves or exceeds a stipulated maximum value.

17. The method according to claim 11, wherein the method, further to the classification of a first voltage sensor as defective, is repeated for the remaining voltage sensors, provided that the number n of remaining voltage sensors is at least three.

18. The method according to claim 17, wherein the method, prior to the detection of a defective voltage sensor, is executed for a number n of voltage sensors, wherein n=nₘᵢₙ, wherein nₘᵢₙ is a minimum number of voltage sensors that is greater than or equal to 5, and, after the detection of the defective voltage sensor, is executed for 3≤n<nₘᵢₙ voltage sensors.

19. The method according to claim 17, wherein, after the classification of the first voltage sensor as defective, the method is repeated for the remaining voltage sensors and, additionally, a check is executed as to whether the first voltage sensor which has been classified as defective continues to fulfil the deviation from the stipulated criterion at least once during a given number of executions of steps (a) to (c) and, if this is not the case, the first voltage sensor is no longer classified as defective, such that the method is executed thereafter with a re-inclusion of the first voltage sensor.

20. A vehicle having an onboard electrical system which is operated at an equal rated voltage, comprising a plurality of controllers, each having at least one voltage sensor, and an evaluation device which is connected to the voltage sensors, and which is designed to receive voltage measurement values measured by a total of n≥3 voltage sensors, wherein the evaluation device is designed to execute the method according to claim 11.
